(19) United States
(12) Patent Application Publication
(10) Pub. No.: US 2013/0224948 A1
(43) Pub. Date: Aug. 29, 2013

(54) METHODS FOR DEPOSITION OF TUNGSTEN IN THE FABRICATION OF AN INTEGRATED CIRCUIT

(71) Applicants: Ralf Richter, Dresden (DE); Jana Rössler, Dresden (DE)

(72) Inventors: Ralf Richter, Dresden (DE); Jana Rössler, Dresden (DE)

(73) Assignee: GLOBALFOUNDRIES INC., Grand Cayman (KY)

(21) Appl. No.: 13/406,566

(22) Filed: Feb. 28, 2012

(51) Int. Cl. H01L 21/768

(52) U.S. Cl. 438/653; 438/675; 257/E21.584; 257/E21.586

(57) ABSTRACT

A method for fabricating an integrated circuit includes providing a semiconductor wafer comprising a hole etched therein, depositing a first layer comprising tungsten onto the semiconductor wafer and into the hole therein, thereby filling the hole with the first layer, and etching the first layer from the semiconductor wafer, wherein etching the first layer results in the formation of a divot above the first layer within the hole. The method may further include depositing a second layer comprising tungsten onto the semiconductor wafer and into the divot formed above the first layer within the hole and polishing the second layer from the semiconductor wafer, wherein polishing the second layer does not remove the second layer deposited into the divot.

### TECHNICAL FIELD

The present disclosure generally relates to methods for the fabrication of integrated circuits. More particularly, the present disclosure relates to methods for deposition of tungsten (W) on semiconductor wafers in the fabrication of integrated circuits.

### BACKGROUND

The deposition, for example by chemical vapor deposition (CVD), of tungsten on a semiconductor wafer (which may have portions of an integrated circuit structure already formed therein) is a part of many integrated circuit fabrication processes. Chemical vapor deposited tungsten has been used as a conducting material to fill contact holes or via holes. The tungsten layer is deposited so as to cover the complete wafer surface and is then etched or polished away, except from the holes. Minimizing process failures during the deposition and etching of tungsten, such as the formation of divots within the holes, results in an improved process yield.

Accordingly, it is desirable to provide improved methods for the deposition of tungsten on semiconductor wafers in the fabrication of integrated circuits. Furthermore, other desirable features and characteristics will become apparent from the subsequent detailed description and the appended claims, taken in conjunction with the accompanying drawings and the foregoing technical field and background.

### BRIEF SUMMARY

The methods provided herein are generally applicable to the fabrication of integrated circuits. In accordance with one embodiment, a method includes providing a semiconductor wafer including a hole etched therein, depositing a first layer including tungsten onto the semiconductor wafer and into the hole therein, thereby filling the hole with the first layer, and etching the first layer from the semiconductor wafer, wherein etching the first layer results in the formation of a divot above the first layer within the hole. The method may further include depositing a second layer including tungsten onto the semiconductor wafer and into the divot formed above the first layer within the hole and polishing the second layer from the semiconductor wafer, wherein polishing the second layer does not remove the second layer deposited into the divot.

In accordance with another embodiment, a method includes providing a semiconductor wafer including a hole etched therein, depositing a protective metal layer onto the semiconductor wafer, and depositing a first layer including tungsten onto the semiconductor wafer and into the hole therein, thereby filling the hole with the first layer, wherein depositing the first layer includes depositing a material including tungsten that has relatively good filling properties. The method may further include etching the first layer from the semiconductor wafer, wherein etching the first layer results in the formation of a divot above the first layer within the hole, depositing a second layer including tungsten onto the semiconductor wafer and into the divot formed above the first layer within the hole, wherein depositing the second layer includes depositing a material including tungsten that has relatively fast deposition properties, and polishing the second layer from the semiconductor wafer, wherein polishing the second layer does not remove the second layer deposited into the divot. The method may further include depositing an ILD layer and etching the ILD layer, wherein etching the ILD layer includes etching the ILD layer above the hole to a depth sufficient for contact with the second layer deposited in the divot.

In accordance with yet another embodiment, a method includes depositing a first layer including tungsten onto a semiconductor wafer, the semiconductor wafer including a hole etched therein, etching the first layer from the semiconductor wafer, depositing a second layer including tungsten onto the semiconductor wafer, and polishing the second layer from the semiconductor wafer.

### BRIEF DESCRIPTION OF THE DRAWINGS

The disclosed methods will hereinafter be described in conjunction with the following drawing figures, wherein like numerals denote like elements, and wherein:

FIGS. 1A-2F are cross-sectional views of a series of integrated circuits illustrating method steps in the fabrication of an integrated circuit including deposition and etching of tungsten as is known in the art; and

FIGS. 3A-3D is a cross-sectional view of a series of integrated circuits illustrating method steps in the fabrication of an integrated circuit including deposition and etching of tungsten in accordance with the present invention.

### DETAILED DESCRIPTION

The following detailed description is merely exemplary in nature and is not intended to limit the invention or the application and uses of the invention. As used herein, the word “exemplary” means “serving as an example, instance, or illustration.” Thus, any embodiment described herein as “exemplary” is not necessarily to be construed as preferred or advantageous over other embodiments. All of the embodiments described herein are exemplary embodiments provided to enable persons skilled in the art to make or use the invention and not to limit the scope of the invention which is defined by the claims. Furthermore, there is no intention to be bound by any expressed or implied theory presented in the preceding technical field, background, brief summary, or the following detailed description.

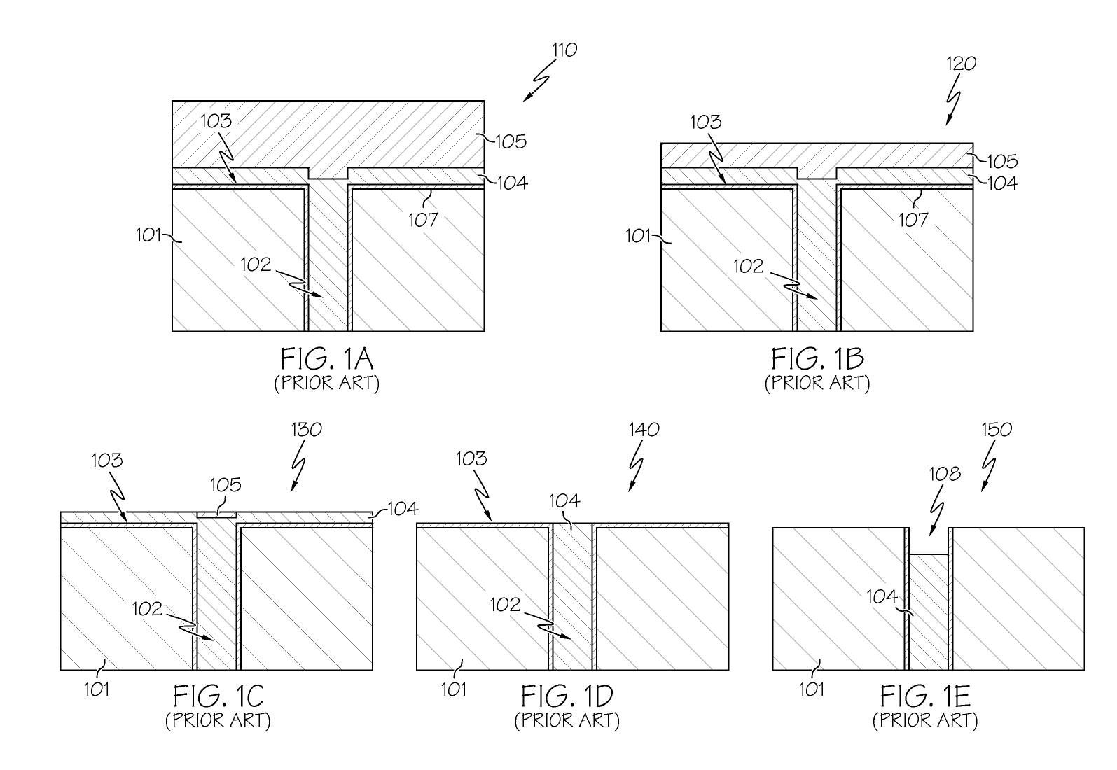

FIGS. 1A-1E are illustrative of a method for the deposition and etching of tungsten on a silicon oxide layer overlying a semiconductor wafer, currently known in the art, that is prone to process failures. The cross-section illustration of semiconductor wafer 110 (FIG. 1A) depicts a silicon oxide layer 101 (for example, tetraethyl orthosilicate (TEOS)) having two layers of tungsten containing materials 104,105 deposited thereon. The semiconductor wafer 110 was prepared and provided in the following manner: A contact hole or a via hole 102 was etched into the silicon oxide layer 101 using techniques that are known in the art. Subsequent to etching of the contact or via hole 102, a protective metal 103 layer was sputtered or otherwise deposited onto the silicon oxide layer 101. The protective metal layer 103 provides a diffusion barrier and serves as a seed layer for the subsequently deposited tungsten. In one example, the protective metal layer 103 may include titanium nitride (TiN). In other examples, the protective metal layer may include Ti, Ta, or TaN.

Tungsten is thereafter deposited onto the protective metal layer 103 in a two-step process, using, for example, tungsten hexafluoride (WF₆) precursor material alone or in combination with other materials. In the first step of the two-step process, a thin layer of a tungsten containing material 104 is deposited over the protective metal layer 103 and into the hole 102. The thin layer of tungsten containing material 104 is selected so as to have relatively good fill properties (i.e., the hole 102 is easily filled with the tungsten containing material without leaving any voids). In one example, the tungsten containing material is deposited using a precursor that contains B. Deposition of the tungsten containing material 104 generally occurs at a relatively slow deposition rate. The deposition of tungsten containing material 104 accordingly results in relatively good fill properties, especially for holes with high aspect ratios. Deposition of tungsten with silicon can be accomplished with the chemical vapor deposition of WF₆ and a precursor including B, for example. Because WF₆ is very reactive, the protective metal layer 103, for example TiN, acts as a barrier between the WF₆ and the silicon oxide layer 101. The thin layer of tungsten containing material 104 is generally deposited to a thickness ranging from about 200 Å to about 800 Å. In the second step, a second layer of tungsten containing material 105 is deposited over the layer of material 104. The second layer of tungsten containing material 105 is selected so as to have relatively fast deposition properties. This increases the speed at which deposition occurs, but results in relatively poor fill properties (as such, it would not be possible to fill the hole 102 using only the deposition of tungsten containing material 105). However, as the hole has already been filled by the thin layer of tungsten containing material 104, good fill properties are not necessary in the second layer of tungsten containing material 105. In one example, the second layer of tungsten containing material 105 is deposited using a Si-containing precursor and a precursor that uses less B than in the deposition of tungsten containing material 104. Again, tungsten can be deposited using chemical vapor deposition of WF₆ and precursor including Si, and less B than with regard to the deposition of tungsten material 104. As a result, the layers containing tungsten materials 104 and 105 exhibit different properties, including different textures, different etch rates, different electronic potentials, and different electrical resistances, among other differences. As shown in wafer 110, the layers 104, 105 are not necessarily planar with respect to one another. For example, a shallow divot 106 due to the filling of the hole 102 with the first layer of tungsten containing material 104 may be present.

Subsequent polishing steps of the method are also shown in FIGS. 1A-1E. Semiconductor wafers 120 (FIG. 1B), 130 (FIG. 1C), and 140 (FIG. 1D), which have increasing amounts of tungsten removed therefrom, were prepared from semiconductor wafer 110, using chemical mechanical planarization (CMP) techniques that are known in the art. As used herein, the term polishing can refer to any known CMP processes, including either wet or dry etching techniques. In FIGS. 1A-1E, removal of the deposited tungsten containing material layers 104,105 above the silicon oxide layer upper surface 107 is illustrated as a three-step process (progression from cross-sectional views 110 through 140). However, it will be appreciated that the tungsten layers 104,105 are currently removed CMP techniques with varying numbers of process steps.

Semiconductor wafer 150 (FIG. 1E), which has the protective metal layer 103 removed, was prepared from semiconductor wafer 140 using known CMP techniques including a chemical slurry. While not intending to be bound by any particular theory, it is postulated that during this last polishing phase, electrochemical transport between the tungsten layer 104 and the CMP slurry causes undesirable removal of some of the tungsten layer 104 within the hole 102, causing a divot 108 to form at the top of the hole 102. It has been observed that divots 108 form randomly, depending partly on the design of the integrated circuit, including the contact density and size.

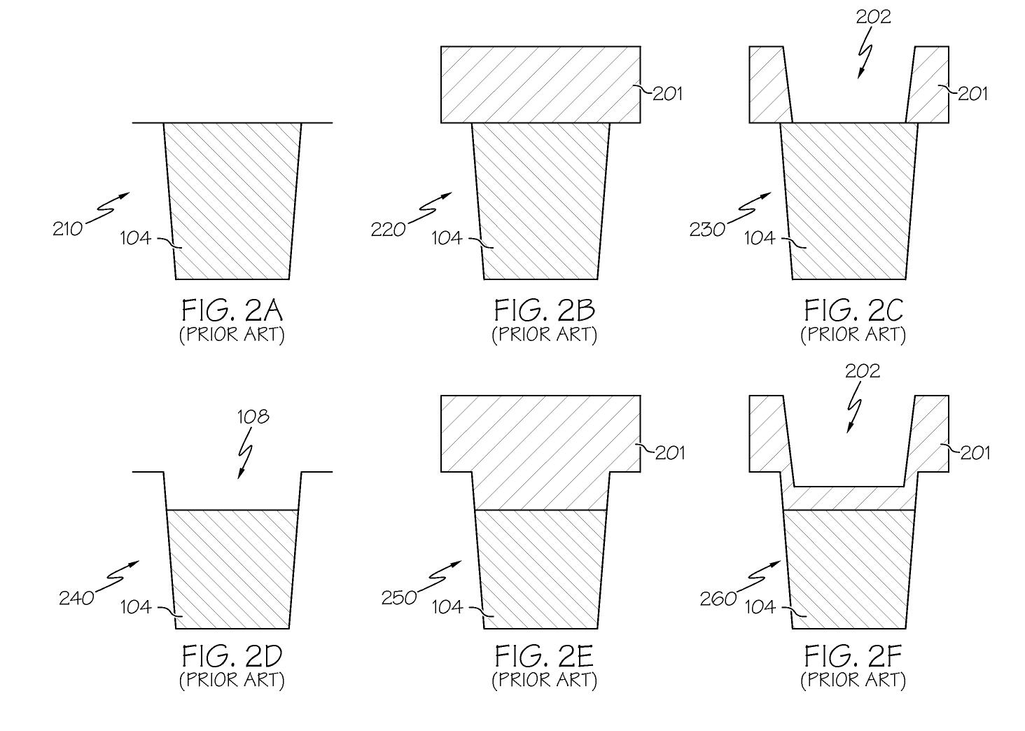

FIGS. 2A-2F illustrate further steps in the fabrication of integrated circuits. Cross-sectional views 210-230 (FIGS. 2A-2C) show the further steps over holes 102 where no divot was formed in the previous fabrication steps, whereas cross-sectional views 240-260 (FIGS. 2D-2F) show the further steps over holes 102 where a divot 108 was formed in the previous fabrication steps. As such, FIGS. 2A-2F are provided to show the undesirability of divots 108, and the contact failures that can occur as a result thereof. Cross-sectional view 210 shows a magnified view of the tungsten layer 104 within the hole 102 without a divot 108. In further processing steps, as shown at cross-sectional view 220, an interlayer dielectric (ILD) layer 201 is deposited on top of the silicon oxide layer 101 and the hole 102. At cross-sectional view 230, this ILD layer 201 is then etched away (202) above the layer of tungsten containing material 104 within the hole 102 to provide direct contact therewith. Where a divot 108 defect is present, however, as shown in cross-sectional views 240, 250 and 260, the ILD layer 201 fills the divot 108 (see cross-sectional view 250). Thereafter, when etching of the ILD layer 201 occurs, the etch 202 may not be deep enough to provide direct contact with the tungsten layer 104 (see cross-sectional view 260). This lack of contact may undesirably cause the resulting integrated circuit to malfunction, reducing the overall yield of the fabricating process. Known solutions to this problem have included longer ILD layer 201 etching, to make a deeper etch. However, this solution causes additional problems, including for example damaging contacts without defects by over-etching. Further, these known solutions become more challenging to perform for smaller technologies (e.g., 28 nm and smaller). As such, solutions are needed to prevent the formation of divots 108 in the first instance.

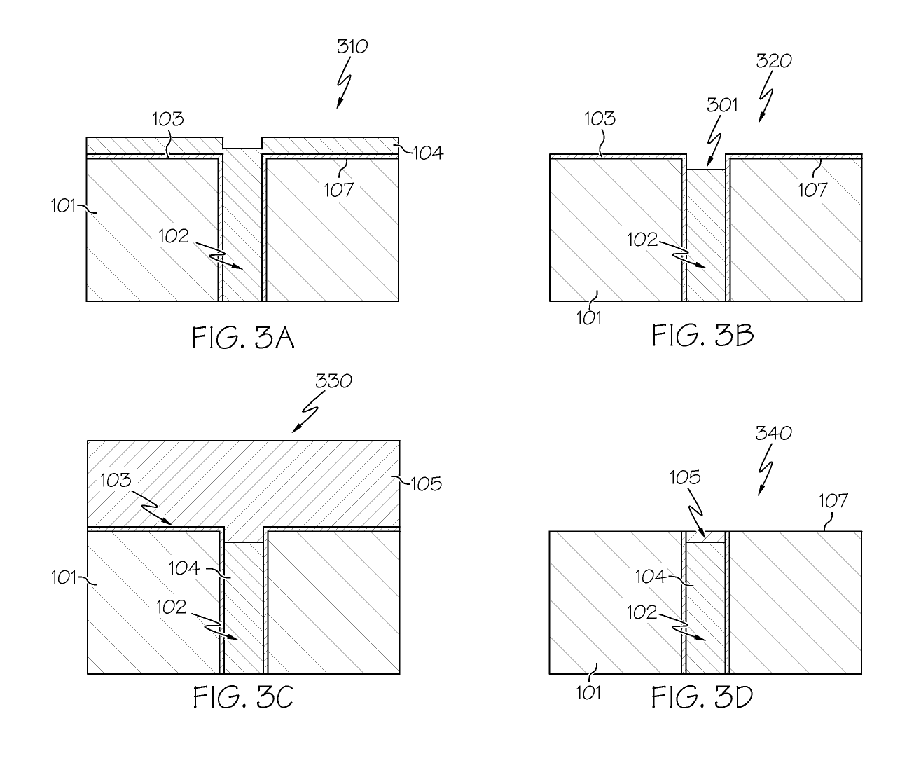

FIG. 3A-3D illustrates an exemplary embodiment of a method in accordance with the present invention. The cross-sectional illustration of semiconductor wafer 310 (FIG. 3A) depicts a silicon oxide layer 101 (for example, tetraethyl orthosilicate (TEOS)) and a contact hole 102 having one layer of a tungsten containing material 104 deposited thereon. The semiconductor wafer 310 was prepared and provided in the following manner: A contact hole or a via hole 102 was etched into the silicon oxide layer 101 using techniques that are known in the art, as discussed above with regard to FIGS. 1A-1E. Subsequent to etching of the contact or via hole 102, a protective metal 103 layer was sputtered or otherwise deposited onto the silicon oxide layer 101. In one example, the protective metal layer 103 may include titanium nitride (TiN).

With continued reference to semiconductor wafer 310, the thin layer of tungsten containing material 104 is thereafter deposited onto the protective metal layer 103, as discussed above with regard to FIGS. 1A-1E. The thin layer of tungsten containing material 104 is generally deposited to a thickness ranging from about 200 Å to about 800 Å.

Thereafter, with reference to semiconductor wafer 320 (FIG. 3B), rather than depositing a second layer of tungsten as in FIGS. 1A-1E (105), etching techniques are used to etch away the layer of tungsten containing material 104 above the protective metal layer 103. Etching may be performed as either wet etching or dry etching, using techniques that are known in the art. During this etching, some of the tungsten layer 104 is removed from the hole 102, resulting in a small divot 301. Divot 301 may range in thickness from about 5 Å to about 20 Å, and is typically observed to be about 10 Å. In an alternative embodiment, CMP may be used in place of etching.

Thereafter, with reference to semiconductor wafer 330 (FIG. 3C), the second layer of tungsten containing material 105 is deposited onto the protective metal layer 103 and also into the divot 301, in the manner as discussed above with regard to FIGS. 1A-1E. While it was previously noted that the tungsten containing material 105 has relatively poor fill properties, the thickness of the divot 301, noted above, is not so thick as to prevent the tungsten layer 105 from fully filling the divot 301. That is, the aspect ratio of the divot formed by the CMP process on wafer 320 is low enough that the tungsten layer 105 can fully fill the divot 301.

With reference now to semiconductor wafer 340 (FIG. 3D), the layer of tungsten containing material 105 and the protective metal layer 103 are polished away using CMP techniques above the upper surface 107 of the silicon oxide layer 101. Here, a divot 108 is not formed as a result of the polishing. Without being bound by theory, it is believed that the tungsten containing material 105 is not susceptible to the random electrochemical transport with the CMP slurry as is the tungsten layer 104, as divot formation has not been observed as a result of polishing as shown with regard to semiconductor wafer 340.

Without the formation of the divot 108, the semiconductor wafer 340 can be further processed in the manner described above with regard to FIGS. 2A-2F, cross-sectional views 210-230, to form an ILD layer with a direct contact to the tungsten layer. As such, the presently described inventive method reduces the frequency of contact failures, and thereby beneficially increases the resulting yield of the integrated circuit fabricating process.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration as claimed in any way. Rather, the foregoing detailed description will provide those skilled in the art with a convenient road map for implementing the exemplary embodiment or exemplary embodiments. It should be understood that various changes can be made in the function and arrangement of elements without departing from the scope herein as set forth in the appended claims and the legal equivalents thereof.

What is claimed is:

1. A method for fabricating an integrated circuit, the method comprising:
providing a semiconductor wafer comprising a hole etched therein, the hole having a substantially constant diameter along its entire length;
depositing a first layer comprising tungsten onto the semiconductor wafer and into the hole therein, thereby completely filling the entire hole with the first layer, wherein depositing the first layer comprising tungsten is performed at a first tungsten deposition rate with first precursor materials;
etching the first layer from the semiconductor wafer, wherein etching the first layer removes a portion of the first layer from within an upper portion of the hole, thereby resulting in the formation of a divot above a remaining portion of the first layer within a lower portion of the hole;
depositing a second layer comprising tungsten onto the semiconductor wafer and into the divot formed above the first layer within the upper portion of the hole so as to completely fill the upper portion of the hole, wherein depositing the second layer comprising tungsten is performed at a second tungsten deposition rate that is faster than the first tungsten deposition rate with second precursor materials that differ from the first precursor materials;
polishing, in a first polishing step, the second layer from the semiconductor wafer so as to remove the second layer from portions of the semiconductor wafer that are above the hole; and
polishing, in a second polishing step performed subsequent to the first polishing step, the semiconductor wafer with a CMP slurry that does not electrochemically interact with a remaining portion of the second layer that remains in the divot subsequent to the first polishing step, wherein the second polishing step does not remove the remaining portion of the second layer deposited into the divot.

2. The method of claim 1, wherein providing the semiconductor wafer comprises providing a semiconductor wafer comprising the hole formed through a single TEOS layer.

3. The method of claim 1, wherein providing the semiconductor wafer comprising a hole etched therein comprises providing a semiconductor wafer with a contact hole or a via hole etched therein.

4. The method of claim 1, further comprising depositing a protective metal layer onto the semiconductor wafer prior to depositing the first layer.

5. The method of claim 4, wherein depositing the protective metal layer comprises depositing a TiN layer.

6. The method of claim 4, wherein depositing the protective metal layer comprises depositing a Ti, Ta, or TaN layer.

7. The method of claim 1, wherein depositing the first layer comprises a chemical vapor deposition procedure.

8. The method of claim 1, wherein depositing the second layer comprises a chemical vapor deposition procedure.

9. (canceled)

10. The method of claim 2, wherein depositing the first layer comprising tungsten comprises depositing W from WF₆ with a precursor comprising a first amount of B.

11. (canceled)

12. The method of claim 10, wherein depositing the second layer comprising tungsten comprises depositing W from WF₆ with a precursor comprising Si and a second amount of B that is less than the first amount of B.

13. The method of claim 1, wherein etching the first layer comprises a wet etch procedure.

14. The method of claim 1, wherein polishing the second layer comprises a chemical mechanical planarization procedure.

15. The method of claim 1, wherein depositing the first layer comprises depositing the first layer to a thickness from about 200 Å to about 800 Å above the hole.

16. The method of claim 1, further comprising depositing an ILD layer after polishing the second layer.

17. The method of claim 16, further comprising etching the ILD layer after depositing the ILD layer.

18. The method of claim 17, wherein etching the ILD layer comprises etching the ILD layer above the hole to a depth sufficient for contact with the second layer deposited in the divot.

19. (canceled)

20. (canceled)

21. The method of claim 12, wherein the second layer comprising tungsten has a texture and an electronic potential that differs from a texture and an electronic potential of the first layer comprising tungsten, and wherein the texture and electronic potential of the second layer comprising tungsten prevents electrochemical transport between the second layer comprising tungsten and the CMP slurry used in the second polishing step.
